(19) United States
(12) Patent Application Publication
(10) Pub. No.: US 2025/0079111 A1
(43) Pub. Date: Mar. 6, 2025

(54) MULTI-BEAM PARTICLE MICROSCOPE WITH IMPROVED ALIGNMENT AND METHOD FOR ALIGNING THE MULTI-BEAM PARTICLE MICROSCOPE, AND COMPUTER PROGRAM PRODUCT

(71) Applicant: Carl Zeiss MultiSEM GmbH, Oberkochen (DE)

(72) Inventors: Joerg Jacobi, Heidenheim (DE); Jonas Bader, Heidenheim (DE)

(21) Appl. No.: 18/956,625

(22) Filed: Nov. 22, 2024

Related U.S. Application Data
(63) Continuation of application No. PCT/EP2023/025222, filed on May 10, 2023.

(30) Foreign Application Priority Data
Jun. 3, 2022 (DE) 10 2022 114 098.9

(51) Int. Cl. H01J 37/02; H01J 37/14; H01J 37/28

(52) U.S. Cl. CPC H01J 37/023; H01J 37/14; H01J 37/28; H01J 2237/024; H01J 2237/1205; H01J 2237/1405

(57) ABSTRACT

For aligning magnetic lenses in a multi-beam particle microscope, an electrically controllable mechanical alignment and fixing mechanism with an actuator system is provided for at least one global alignable magnetic lens. The mechanism is configured to mechanically align and mechanically fix a position of the at least one alignable magnetic lens in the particle optical beam path in a plane orthogonal to the optical axis of the multi-beam particle microscope. A controller is configured to electrically control the electrically controllable mechanical alignment and fixing mechanism.

### CROSS-REFERENCE TO RELATED APPLICATIONS

The present application is a continuation of, and claims benefit under 35 USC 120 to, international application No. PCT/EP2023/025222, filed May 10, 2023, which claims benefit under 35 USC 119 of German Application No. 10 2022 114 098.9, filed Jun. 3, 2022. The entire disclosure of each of these applications is incorporated by reference herein.

### FIELD

The disclosure relates to a multi-beam particle microscope with improved alignment, to a method for aligning the multi-beam particle microscope, and to an associated computer program product.

### BACKGROUND

With the continuous development of ever smaller and ever more complex microstructures such as semiconductor components, there is a desire to further develop and optimize planar production techniques and inspection systems for producing and inspecting small dimensions of the microstructures. By way of example, the development and production of the semiconductor components involves monitoring the design of test wafers, and the planar production techniques involve process optimization for a reliable production with a high throughput. Moreover, there have been recent demands for an analysis of semiconductor wafers for reverse engineering and for a customer-specific, individual configuration of semiconductor components. Therefore, there is a desire for an inspection mechanism which can be used with a high throughput for examining the microstructures on wafers with a high accuracy.

Typical silicon wafers used in the production of semiconductor components have diameters of up to 300 millimeters (mm). Each wafer is divided into 30 to 60 repeating regions (“dies”) with a size of up to 800 square millimeters (mm²). A semiconductor apparatus comprises a plurality of semiconductor structures, which are produced in layers on a surface of the wafer by planar integration techniques. Semiconductor wafers typically have a plane surface on account of the production processes. The structure size of the integrated semiconductor structures in this case extends from a few um to the critical dimensions (CD) of 5 nanometers (nm), with the structure sizes becoming even smaller in the near future; in future, structure sizes or critical dimensions (CD) are expected to be less than 3 nm, for example 2 nm, or even under 1 nm. In the case of the aforementioned small structure sizes, it is desriable to detect defects in the size of the critical dimensions quickly in a very large area. For several applications, the desired accuracy of a measurement provided by inspection equipment is even higher, for example by a factor of two or one order of magnitude. By way of example, a width of a semiconductor feature is measured with an accuracy of below 1 nm, for example 0.3 nm or even less, and a relative position of semiconductor structures are determined with an overlay accuracy of below 1 nm, for example 0.3 nm or even less.

The MSEM, a multi-beam scanning electron microscope, is a relatively new development in the field of charged particle systems (charged particle microscopes, CPMs). By way of example, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a plurality of individual electron beams, which are arranged in a field or grid. By way of example, 4 to 10,000 individual electron beams can be provided as primary radiation, with each individual electron beam being separated from an adjacent individual electron beam by a pitch of 1 to 200 micrometers. By way of example, an MSEM has approximately 100 separate individual electron beams (“beamlets”), which are arranged for example in a hexagonal grid, with the individual electron beams being separated by a pitch of approximately 10 micrometers (μm). The plurality of charged individual particle beams (primary beams) are focused on a surface of a sample to be examined by way of a common objective lens. By way of example, the sample can be a semiconductor wafer which is secured to a wafer holder mounted on a movable stage. During the illumination of the wafer surface with the charged primary individual particle beams, interaction products, for example secondary electrons or backscattered electrons, emanate from the surface of the wafer. Their start points correspond to those locations on the sample on which the plurality of primary individual particle beams are focused in each case. The amount and the energy of the interaction products depend on the material composition and the topography of the wafer surface. The interaction products form a plurality of secondary individual particle beams (secondary beams), which are collected by the common objective lens and which are incident on a detector arranged in a detection plane as a result of a projection imaging system of the multi-beam inspection system. The detector comprises a plurality of detection regions, each of which comprises a plurality of detection pixels, and the detector captures an intensity distribution for each of the secondary individual particle beams. An image field of, for example, 100 μm×100 μm is obtained in the process.

Certain known multi-beam electron microscopes comprise a sequence of electrostatic and magnetic elements. At least some of the electrostatic and magnetic elements are adjustable in order to adapt the focus position and the stigmation of the plurality of charged individual particle beams. Such known multi-beam systems moreover comprise at least one cross-over plane of the primary or the secondary charged individual particle beams. Moreover, the systems comprise detection systems to make the adjustment easier. The multi-beam particle microscopes comprise at least one beam deflector (“deflection scanner”) for collective scanning of a region of the sample surface via the plurality of primary individual particle beams in order to obtain an image field of the sample surface.

Further details regarding a multi-beam electron microscope and a method for operating same are described in the international patent application with the application number WO 2021239380 A1, the disclosure of which is fully incorporated by reference in the present patent application.

An alignment of the multi-beam electron microscope, or more generally of a multi-beam particle microscope, is generally considered for precision applications. One aspect of the alignment is the alignment of magnetic lenses of the system. These magnetic lenses can be so-called global magnetic lenses, where substantially all of the charged particles or all of the charged individual particle beams pass through these global magnetic lenses. It is therefore desirable for these lenses to be therefore aligned particularly accurately. Moreover, the fact is that, on account of the geometric dimensions of such a magnetic lens, in general the magnetic field generated in the lens cannot be deduced exactly. To put it another way, the magnetic fields of lenses manufactured identically within the scope of the manufacturing accuracy may indeed be measurably different from one another, which is why an individual lens alignment is used.

In accordance with certain known approaches, the magnetic lenses in a multi-beam particle microscope are aligned mechanically, experienced technicians performing the alignment of the magnetic lenses manually. Such an alignment often takes several weeks or even months; it is carried out with simultaneous observation of a multi-beam particle microscope image. Screws on the exterior of the multi-beam particle microscope or the housing thereof are adjusted in order to align the magnetic lenses. The alignment and subsequent fixing of the magnetic lenses are normally carried out during the commissioning of the multi-beam particle microscope in production; afterwards, the alignment normally remains unchanged and is carried out on site at the customer's premises only after module exchange or magnetic lens exchange. In this case, the renewed alignment on site at the customer's premises is typically more difficult since at the customer's premises the multi-beam particle microscope is often incorporated in a production installation and the associated process chain. Long and expensive outage times in a production installation may therefore occur, which are desirably avoided.

US 2013/0299697 A1 discloses a charged particle beam applied apparatus for observing a sample, provided with: a beam-forming section that forms a plurality of charged particle beams on a sample; an energy control unit that controls the incident energy of the plurality of charged particle beams that are irradiated onto the sample; a beam current control unit that controls the beam current of the plurality of charged particle beams that are irradiated onto the sample; and a beam arrangement control unit that controls the arrangement in which the plurality of charged particle beams is irradiated onto the sample. The beam-forming section includes a beam splitting electrode, a lens array upper electrode, a lens array middle electrode, a lens array lower electrode and a movable stage, and functions as the beam current control unit or the beam arrangement control unit through selection, by the movable stage, of a plurality of aperture pattern sets. US 2013/0299697 A1 does not deal with the specific problem of alignment of particle optical components. An alignment of global magnetic lenses is not addressed.

GB 894 569 A published in 1962 discloses a device for compensating axial astigmatism of electron lenses. It refers to a single beam system and a specific objective lens as an electron lens. Correction coils are movably arranged around the objective lens and outside the vacuum chamber. The objective lens itself is not mechanically aligned.

### SUMMARY

The disclosure seeks to provide an improved multi-beam particle microscope with respect to the alignment of magnetic lenses. The alignment is intended to be able to be carried out in particular more rapidly and if possible also more precisely.

In the case of single-beam particle microscopes, an alignment of magnetic lenses in accordance with certain known techniques is no longer carried out only mechanically, but rather via deflectors that deflect the particle beam such that it is guided through the magnetic lens centre. It therefore appears to be an option in the case of a multi-beam particle microscope, too, to perform the alignment or at least the fine alignment via electrical and/or magnetic deflectors. However, following thorough investigations by the inventors, this approach proves to involve some issues.

A multi-beam particle microscope typically uses landing energies in the range of approximately 0.3 keV to approximately 5 keV, for which purpose relatively high beam energies of approximately 30 keV are used within the column. On account of these high beam energies, high field strengths are also used in order to be able to deflect the individual particle beams within the column. The use of high deflection field strengths in turn can involve high voltages and/or high currents, which can entail parasitic effects that adversely affect the beam quality. Therefore, it is better to carry out a mechanical alignment in the case of a multi-beam particle microscope.

The present disclosure therefore proposes an electrically controllable mechanical alignment. This allows a rapid alignment with at the same time improved precision.

In accordance with a first aspect, the disclosure relates to a multi-beam particle microscope for sample inspection, comprising the following:
at least one particle source configured to generate a divergent beam of charged particles;
a condenser lens system, through which the beam of charged particles passes;
a multi-beam generator, which is arranged downstream of the condenser lens system in the direction of the beam path of the particles in such a way that at least some charged particles pass through openings in the multi-beam generator in the form of a plurality of individual particle beams, and which is configured to generate a first field of a multiplicity of charged first particle beams;
a first particle optical unit with a first particle optical beam path, configured to image the generated first individual particle beams onto a sample surface in the object plane such that the first particle beams are incident on the sample surface at incidence locations, which form a second field;
a detection system with a multiplicity of detection regions that form a third field;
a second particle optical unit with a second particle optical beam path, configured to image second individual particle beams, which emanate from the incidence locations in the second field, onto the third field of the detection regions of the detection system;
a magnetic and/or electrostatic objective lens, through which both the first and the second individual particle beams pass;
a beam switch, which is arranged in the first particle optical beam path between the multi-beam generator and the objective lens and which is arranged in the second particle optical beam path between the objective lens and the detection system;
wherein the condenser lens system and/or the first particle optical unit and/or the second particle optical unit comprise(s) at least one alignable magnetic lens arranged in a housing via a mount in such a way that charged particles pass through it,
wherein an electrically controllable mechanical alignment and fixing mechanism with an actuator system is furthermore provided for the at least one alignable magnetic lens, the mechanism being configured to mechanically align and mechanically fix a position of the at least one alignable magnetic lens in the particle optical beam path in a plane orthogonal to the optical axis of the multi-beam particle microscope, and
a controller configured to electrically control the electrically controllable mechanical alignment and fixing mechanism.

The charged particles can be, e.g., electrons, positrons, muons or ions or other charged particles. The charged particles can be electrons generated e.g. using a thermal field emission source (TFE). However, other particle sources can also be used.

The individual particle beams can be arranged in a grid arrangement, that is to say an arrangement of the individual particle beams relative to one another can be fixed or can be selected. This can be a regular grid arrangement, which can provide, for example, a square, rectangular or hexagonal arrangement of the individual particle beams relative to one another, in particular with uniform spacing. The number of individual particle beams can be 3 n (n−1)+1, where n is any natural number.

The multi-beam particle microscope can be a system operating with a single column, but it is also possible for the multi-beam particle microscope to be realized via a multi-column system.

The condenser lens system and/or the first particle optical unit and/or the second particle optical unit comprise(s) at least one alignable magnetic lens arranged in a housing via a mount in such a way that charged particles pass through it. This alignable magnetic lens can be, in general, any of the magnetic lenses typically present in the multi-beam particle microscope. It can be a global magnetic lens, through which a multiplicity of, and for example all, individual particle beams pass; however, it is also possible for the alignable magnetic lens to be situated upstream of the multi-beam generator in the particle optical beam path and, instead of as yet individual particle beams, for a diverging beam of charged particles, for example, to pass through the lens. Examples of alignable magnetic lenses are condenser lenses, field lenses and projection lenses. In general, an alignable magnetic lens in the context of this patent application is understood to mean a magnetic lens whose position in the particle optical beam path is alterable in a targeted manner in a plane orthogonal to the optical axis of the system. In this case, the aim of the alignment is to guide the beam of charged particles or the multiplicity of individual particle beams parallel to the optical axis through the magnetic lens centre. In this case, generally, the magnetic lens centre does not correspond exactly to the geometric centre of the magnetic lens, which, as described above, firstly involves the alignment of magnetic lenses and secondly makes the alignment more difficult, in general.

The mount of the alignable magnetic lens keeps the latter in its position, in general, but allows the freedom of movement used for the alignment process. A typical mount for a magnetic lens is a so-called clamping ring, for example, which clamps a lens pot of the magnetic lens (the magnetic lens can be subdivided into a lens pot and a lens cover). The mount is suitably connected to a housing in which the alignable magnetic lens is arranged; this housing can be for example an exterior housing of the multi-beam particle microscope.

According to the disclosure, an electrically controllable mechanical alignment and fixing mechanism with an actuator system is provided for the at least one alignable magnetic lens, the mechanism being configured to mechanically align and mechanically fix a position of the at least one alignable magnetic lens in the particle optical beam path in a plane orthogonal to the optical axis of the system. The aforementioned plane is also referred to hereinafter as alignment plane. Maintaining mechanical alignment and fixing can avoid the parasitic effects with negative effects on the beam quality that occur in the case of an electrical and/or magnetic deflection. At the same time, the electrical control can help make it possible to improve the accuracy and reproducibility of the alignment which are not attainable in the case of a purely manual mechanical alignment. The electrical control makes it possible to achieve an improvement by approximately a factor of 100 with respect to the attainable accuracy in the alignment.

Moreover, a skillful arrangement of the electronically controllable mechanical alignment and fixing mechanism makes it possible to align even such magnetic lenses which were previously not alignable manually. Specifically, not every magnetic lens in a multi-beam particle microscope is actually accessible for alignment through an outer housing without problems. It is immediately evident that if alignment screws and fixing screws are used for the mechanical alignment and fixing, for example, a technician specifically has to get at these screws during a purely manual mechanical alignment, which is typically the case if the screws to be adjusted are arranged near the housing wall of the multi-beam particle microscope, this wall normally being embodied in tubular fashion. For magnetic lenses further inside, a manual alignment in this manual way is generally not possible.

The electrically controllable mechanical alignment and fixing mechanism with an actuator system according to the disclosure can be embodied integrally or in multipartite fashion, in general. It is also possible for the electrically controllable mechanical alignment and fixing mechanism to comprise a multiplicity of electrically controllable mechanical alignment and fixing mechanism; the term “mechanism” thus by definition encompasses both the singular and the plural of “mechanism”. In accordance with one embodiment of the disclosure, the electrically controllable mechanical alignment and fixing mechanism is multipartite and comprises an electrically controllable mechanical alignment mechanism and an electrically controllable mechanical fixing mechanism in the form of two separate structural units. In this case, it holds true once again that these structural units can be embodied integrally or in multipartite fashion, and it is also possible again for an electrically controllable mechanical alignment mechanism to comprise a multiplicity of electrically controllable mechanical alignment mechanism and for an electrically controllable mechanical fixing mechanism to comprise a multiplicity of electrically controllable mechanical fixing mechanism.

However, instead of a functional separation of alignment mechanism, on the one hand, and fixing mechanism, on the other hand, it is also possible, of course, to provide a combination of an electrically controllable mechanical alignment and fixing mechanism with an actuator system. The functional subdivision can ultimately depend on the constructional type of implementation of the electrically controllable mechanical alignment and fixing mechanism with an actuator system.

In general, an alignment or aligning is understood to mean adjusting the position of the magnetic lens in the alignment plane. In the case of the fixing, on the other hand, the position adjusted by the alignment is fixed. A fixing is thus a restraint and the two terms are used synonymously in the context of this patent application. In this case, the fixing or restraining force is stronger than the prevailing forces and can also be stronger than the force of the actuator provided. In the context of this patent application, an actuator is defined generally as a structural unit pertaining to drive technology which converts an electrical signal into a mechanical movement and thus actively intervenes in the controlled process, namely the alignment and/or fixing. According to the disclosure, the electrical signal or electrical signals is or are generated by a controller, which can be the controller or a module of the controller of the multi-beam particle microscope itself; however, it is also possible, in general, to provide the controller separately.

In the context of this patent application, the term alignment mechanism implies mounting or guiding of a mechanism for the alignment. In this case, the mounting or guiding can be implemented by way of customary bearings such as, for example, sliding bearings or by way of forced guidance via joints. Examples thereof are a hexapod, parallel kinematics, shear kinematics, flexures, etc. Sliding bearings can mean that static friction has to be overcome. This makes a manual alignment more difficult because the point at which the static friction is overcome is unforeseeable and abrupt changes in the adjustment may occur. In this respect, a motorized actuator system can lower the threshold of the static friction for example by way of vibrations such as ultrasonic vibrations, for instance.

The actuator system is limited by the associated force, the range and the resolution or accuracy. In general, actuators that are already known per se can be used for the disclosure. By way of example, linear or rotary motors and combinations thereof are suitable, in general. Piezoelements are also known, for example piezo-stacks with low range and high force or piezo-drives with arbitrary range but low force. Gear mechanisms for transformation can likewise be used (for example screws in threads which are driven by a rotary motor; the rotary movement is thus converted into a linear movement). Pneumatic or hydraulic actuators are also known and suitable in general.

In accordance with one embodiment of the disclosure, the electrically controllable mechanical alignment mechanism comprises as actuator a stepper motor with gear mechanism. The gear mechanism is used for transformation and a corresponding selection of the gear mechanism makes it possible to attain a high accuracy in the alignment, for example an accuracy of 0.1 μm or better. By contrast, a typically attainable accuracy in the purely manual mechanical alignment is only approximately 10 μm.

Additionally or alternatively, an electrically controllable mechanical fixing mechanism comprises as actuator a combination comprising a stepper motor and a piezoelement. This combination can be used together with a fixing screw as a fixing mechanism. In this case, it is possible to use the first actuator with the stepper motor for first fixing of the fixing mechanism such as a fixing screw, for example, and only afterwards is use made of the second actuator in the form of the piezoelement. In this case, the piezoelement can exert the last contact pressure on the fixing mechanism used, such as a fixing screw, for example, and thus allows a better fixing overall.

In general, in accordance with one embodiment of the disclosure, the electrically controllable mechanical fixing mechanism comprises at least one two-stage actuator system for generating a contact pressure for the fixing mechanism. It is also possible to provide for example a three-stage actuator system or a four-stage actuator system, etc. In addition, it is possible to supplement the combination of actuators with a mechanism for increasing and/or releasing the contact force; additionally or alternatively, a pneumatic system can also be provided.

In accordance with one embodiment of the disclosure, actuators used are electrically load-free during operation of the multi-beam particle microscope, i.e., an actuator used involves no supply current or no supply voltage during operation of the multi-beam particle microscope. However, there still exists a mechanical load on the actuator, of course. In this case, operation should be understood to mean normal operation of the multi-beam particle microscope, i.e., in other words routine operation after alignment and fixing have been concluded. The electrical load-freedom thus avoids possible parasitic effects on account of fields present, and the operation of the multi-beam particle microscope is more energy-saving and more sustainable.

In accordance with one embodiment of the disclosure, the electrically controllable mechanical alignment mechanism is configured for a Cartesian alignment and comprises two first alignment units arranged orthogonally to one another in order to align the position of the at least one alignable magnetic lens within the plane (alignment plane) orthogonal to the optical axis of the multi-beam particle beam system. In this case, the orthogonal arrangement of the two first alignment units with respect to one another relates to the direction in which alignment is effected via each of the two first alignment units. In this case, the two first alignment units can be structurally identical, but they need not be structurally identical. In addition, it is possible for the bearing regions or interaction regions of the two first alignment units with the alignable magnetic lens or the mount thereof to be arranged such that the sections between bearing region and optical axis of the multi-beam particle microscope form a right angle with one another. Owing to the rotational symmetry normally afforded for the magnetic lenses, this enables the best possible attachment points and the most efficient alignment of the alignable magnetic lens in the particle optical beam path.

In accordance with one embodiment of the disclosure, each of the two first alignment units arranged orthogonally to one another is arranged on the housing and each of the first alignment units comprises a pressure screw which is movable within the plane orthogonal to the optical axis via an actuator assigned to it and which is coupled to the at least one magnetic lens via the mount of the magnetic lens in order to alter the position thereof. According to the disclosure, a thrust force that acts on such a pressure screw is typically more than 150 newtons, such as more than 170 newtons and for example more than 180 newtons. In accordance with one embodiment of the disclosure, the mount of the magnetic lens is embodied as a clamping ring and the pressure screw presses onto this clamping ring from outside.

In accordance with one embodiment of the disclosure, a counterbearing is in each case provided on the housing at a position diametrically opposite the first alignment unit in relation to the optical axis. The counterbearing can be a spring assembly, for example.

In accordance with an alternative embodiment of the disclosure, an associated second alignment unit, in particular a structurally identical second alignment unit, is in each case provided on the housing at a position diametrically opposite the first alignment unit in relation to the optical axis, wherein the controller is configured to control the mutually associated first and second alignment units oppositely in coordination with one another. The controller thus brings about a change in position by dx, for example, at the first alignment unit and a change in position by correspondingly-dx at the associated second alignment unit. The use of mutually associated first and second alignment units can allow a further increase in precision in the alignment, since possible inaccuracies on the part of the counterbearing do not occur or are replaced by an accurately known position of the second alignment unit.

In accordance with one embodiment of the disclosure, the electrically controllable mechanical fixing mechanism comprises a plurality of separate fixing units, such as fixing screws, which each act on an element of the mount of the at least one alignable magnetic lens and thereby fix the position of the at least one alignable magnetic lens. It is possible to provide for example two or three or four or even more fixing units. It can be desirable to provide four separate fixing units, which are provided in a manner alternating with first and second alignment units circumferentially on the outside relative to the alignable magnetic lens, for example. In this example, therefore, a fixing unit can be situated between two alignment units (regardless of whether this is a first or a second alignment unit).

In accordance with one embodiment of the disclosure, the fixing is effected via frictional force or via geometric blocking. A fixing via frictional force can be desirable for example if the mount of the alignable magnetic lens is not fixedly connected to the lens. By way of example, if a clamping ring is provided as the mount of the magnetic lens, this can only move axially and is not connected to the lens. A fixing of the clamping ring then indirectly fixes the position of the magnetic lens as well, specifically by way of the frictional force resulting from the contact pressure of the fixing mechanism. If the mount or the clamping ring is not fixedly connected to the lens, then this can enable a freer movement during the alignment of the magnetic lens.

In accordance with an alternative embodiment of the disclosure, the mount, and for example a clamping ring, is fixed to the lens and follows it during the alignment. As a result of fixing screws being fitted, the movement of the lenses is then geometrically blocked, specifically ideally both axially and radially.

In accordance with one embodiment of the disclosure, a fixing direction is both oblique with respect to the optical axis of the multi-beam particle microscope and oblique with respect to the alignment plane. This can result in both a radial and an axial fixing of the alignable magnetic lens via the mount such as the clamping ring, for example.

In accordance with one embodiment of the disclosure, the plurality of fixing units are each arranged between alignment units adjacent to one another or between an alignment unit and a counterbearing adjacent to the alignment unit. Adjacent relates to the circumferential direction around the magnetic lens. This can enable a very uniform and secure fixing.

In accordance with a further embodiment of the disclosure, the electrically controllable mechanical alignment and fixing mechanism is not designed in the form of two functionally different separate structural units, but rather as a combined electrically controllable mechanical alignment and fixing mechanism. In contrast to the above-described embodiment variant with functionally separate structural units, this embodiment variant of the disclosure is not retrofittable in existing systems. In this embodiment variant, for example, the alignable magnetic lens can be coupled to the actuator via a fixed connection such as a flexure, for example, such that the actuator can shift the magnetic lens back and forth. In this way, it is also possible for only exactly one actuator to be used per alignment direction, i.e. for example in the x-direction or in the y-direction; a counterbearing such as a spring assembly is no longer necessary, nor is there any need to provide first and second alignment units opposite one another.

In accordance with one embodiment of the disclosure, the combined electrically controllable mechanical alignment and fixing mechanism comprises a plurality of structurally identical combined electrically controllable mechanical alignment and fixing mechanism. It is possible, for example, to provide two combined electrically controllable mechanical alignment and fixing mechanism such that a Cartesian alignment can be realized.

In accordance with one embodiment of the disclosure, the at least one alignable magnetic lens comprises a lens pot and a lens cover, wherein the lens pot and/or the lens cover are/is alignable and fixable independently of one another via the electrically controllable mechanical alignment and fixing mechanism. It is possible, for example, to provide per alignable magnetic lens a total of two electrically controllable mechanical alignment and fixing mechanism each with an actuator system, which, as already described above, can be subdivided into a plurality of mechanisms and structural units and/or alignment units. The separate aligning of lens pot, on the one hand, and lens cover, on the other hand, affords that a possible tilt of the alignable magnetic lens can also be corrected as a result.

Specifically, if lens pot, on the one hand, and lens cover, on the other hand, are not seated centrally one above the other, then this corresponds to a tilting of the axis of the magnetic field. What is of interest here is that a tilting can be simulated in this way, without a mechanical component part actually having to be tilted for this purpose.

In accordance with a further embodiment of the disclosure, the at least one alignable magnetic lens is furthermore alignable and fixable in the direction of the optical axis of the system via the or via a further electrically controllable mechanical alignment and fixing mechanism. In other words, an alignment in the z-direction can also be performed with a corresponding actuator system.

In accordance with a further embodiment of the disclosure, the multi-beam particle microscope comprises a user interface for the controller. It is thus possible for the control of the electrically controllable mechanical alignment and fixing mechanism to be performed electrically via the user interface. The user interface can also comprise an image display unit in order to display a particle optical image. The latter may have been recorded with a current alignment adjustment, for example, and may enable a technician to draw conclusions about the status or the progress of the alignment.

In accordance with one embodiment of the disclosure, the user interface is provided remotely from the multi-beam particle microscope and is set up for remote maintenance of the multi-beam particle microscope. The possibility for remote maintenance is a consequence of the fact that the mechanical alignment need no longer be carried out manually by a technician on site. The fact, too, that a multi-beam particle microscope, at the customer's premises, is often embedded in a process chain or production installation that is difficult to access now no longer poses any problem whatsoever for the alignment of the magnetic lenses. Moreover, it is possible, in general, to align more magnetic lenses than is possible with certain known techniques, since the actuator system and the corresponding lines can be concomitantly integrated in the multi-beam particle microscope from the outset. Accessibility in the vicinity of the housing of the particle beam microscope is not necessarily required any more. In addition, the electrically controllable mechanical alignment and fixing via an actuator system affords that an alignment can be logged. It is also possible to leave an alignment point and subsequently head for it again precisely, which is precluded in practice via a manual alignment. Moreover, it is possible to automate an alignment altogether and to develop alignment algorithms for the alignment in order to rapidly and efficiently realize the best adjustments for the magnetic lenses.

In accordance with a further aspect of the disclosure, the disclosure relates to a method for aligning the multi-beam particle microscope as described above in multiple embodiment variants, the method comprising the following steps:
a) operating the multi-beam particle microscope with a multiplicity of N actuated magnetic lenses, each comprising an electrically controllable mechanical alignment and fixing mechanism with an actuator system, wherein each actuator system allows the movement of one of the N magnetic lenses with one or a plurality of degrees of freedom f. The number of degrees of freedom available in total during the aligning of the actuated magnetic lenses is thus given by the summation of all degrees of freedom f of all the actuated magnetic lenses. Thus, by way of example, if five magnetic lenses each have two actuated degrees of freedom, then this results in a total of 10 degrees of freedom. However, it is also possible for some lenses to have only one degree of freedom, while other magnetic lenses have a plurality of degrees of freedom, for example two, three or even more degrees of freedom, specifically if, on the one hand, the lens pot and, on the other hand, the lens cover are individually alignable.
b) ascertaining a sensitivity of a change in position for each actuated magnetic lens and per degree of freedom of the actuated magnetic lens and ascertaining associated influence vectors on the basis of the ascertained sensitivities.
c) generating a particle optical image via the multi-beam particle microscope and ascertaining an image aberration.
d) determining a sum aberration vector for the ascertained image aberration.
e) singular value decomposition of the sum aberration vector with respect to the ascertained influence vectors and, on the basis thereof, ascertaining manipulated variables for each actuated magnetic lens and for each degree of freedom of the actuated magnetic lens, and
f) electrically controlling the mechanical alignment and fixing mechanism of the actuated magnetic lenses via the controller in accordance with the ascertained manipulated variables in order to reduce or eliminate the image aberration.

Accordingly, a method according to the disclosure is based on linear systems theory. It is assumed that individual elements behave linearly and that the behaviour of the overall system is constituted linearly from the individual elements. This assumption of linear systems theory is always valid at least regionally.

In accordance with one embodiment of the disclosure, the method furthermore comprises the following step:
g) generating a further optical image via a multi-beam particle microscope and ascertaining a residual image aberration;
h) iteratively carrying out method steps d) to g) if the residual image aberration is greater than a predetermined upper limit.

This iterative procedure is helpful if, as a result of non-linearities, for example, a sum aberration vector below a threshold cannot immediately be attained.

In accordance with a further embodiment of the disclosure, the method furthermore comprises the following:
ascertaining influence vectors for various operating points of the multi-beam particle microscope; and/or
storing the influence vectors in a look-up table.

This means that an alignment of the multi-beam particle microscope becomes possible in a tailored manner for each operating point of the multi-beam particle microscope, which overall increases the resolution and accuracy achievable with the multi-beam particle microscope. In this case, various operating points are understood to mean for example various beam currents, various landing energies, various working distances, etc. It is also possible to include various further ambient parameters of the multi-beam particle microscope in the operating point definition, such as, for example, the ambient temperature around the multi-beam particle microscope. Depending on the choice of the operating point, it is then possible to call up or set the best possible alignment via the look-up table.

In accordance with a further embodiment of the disclosure, the method is carried out in the form of remote maintenance of the multi-beam particle microscope. A systems engineer on site is no longer absolutely necessary at least as far as the alignment itself is concerned, which saves time and costs.

In accordance with a third aspect of the disclosure, the disclosure relates to a computer program product having a program code for carrying out the method as described above in a plurality of embodiment variants. In this case, the program code can be programmed in any desired programming language. It is possible for the program code to be subdivided into a plurality of modules. The program code can be executed for example by way of the controller of the multi-beam particle microscope or by way of an associated computer system.

### BRIEF DESCRIPTION OF THE DRAWINGS

The disclosure will be understood even better with reference to the accompanying figures, in which:

FIG. 1 shows a schematic illustration of a multi-beam particle microscope (MSEM);

FIG. 2 schematically shows aspects of a Cartesian alignment of a magnetic lens;

FIG. 3 schematically shows an electrically controllable mechanical alignment and fixing of a global magnetic lens in accordance with a first embodiment;

FIG. 4 schematically shows an electrically controllable mechanical alignment and fixing of a global magnetic lens in accordance with a second embodiment;

FIG. 5 schematically shows an electrically controllable mechanical alignment and fixing of a global magnetic lens in accordance with a third embodiment;

FIG. 6 schematically shows an electrically controllable mechanical alignment mechanism comprising a stepper motor with gear mechanism;

FIG. 7 schematically shows an electrically controllable mechanical fixing mechanism comprising a two-stage actuator system with a stepper motor and a piezoelement;

FIG. 8 illustrates a functional principle of the two-stage actuator system illustrated in FIG. 7; and

FIG. 9 schematically illustrates a method according to the disclosure for aligning a multi-beam particle microscope.

### DETAILED DESCRIPTION

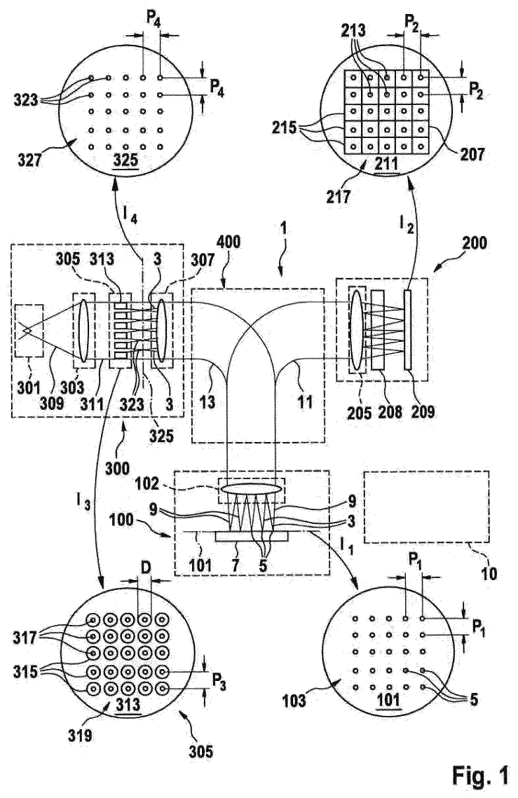

FIG. 1 is a schematic illustration of a particle beam system 1 in the form of a multi-beam particle microscope 1, which uses a plurality of particle beams. The particle beam system 1 generates a plurality of particle beams which are incident on an object to be examined in order to generate there interaction products, for example secondary electrons, which emanate from the object and are subsequently detected. The particle beam system 1 is of the scanning electron microscope (SEM) type, which uses a plurality of primary particle beams 3 which are incident on a surface of the object 7 at a plurality of locations 5 and produce there a plurality of electron beam spots, or spots, that are spatially separated from one another. The object 7 to be examined can be of any desired type, e.g. a semiconductor wafer or a biological sample, and can comprise an arrangement of miniaturized elements or the like. The surface of the object 7 is arranged in a first plane 101 (object plane) of an objective lens 102 of an objective lens system 100.

The enlarged detail I1 in FIG. 1 shows a plan view of the object plane 101 having a regular rectangular field 103 of incidence locations 5 formed in the first plane 101. In FIG. 1, the number of incidence locations is 25, which form a 5×5 field 103. The number 25 of incidence locations is a number chosen for reasons of simplified illustration. In practice, the number of beams, and hence the number of incidence locations, can be chosen to be significantly greater, such as, for example, 20×30, 100×100 and the like.

In the illustrated embodiment, the field 103 of incidence locations 5 is a substantially regular rectangular field having a constant pitch P1 between adjacent incidence locations. Exemplary values of the pitch P1 are 1 micrometre, 10 micrometres and 40 micrometres. However, it is also possible for the field 103 to have other symmetries, such as a hexagonal symmetry, for example.

A diameter of the beam spots shaped in the first plane 101 can be small. Exemplary values of the diameter are 1 nanometre, 5 nanometres, 10 nanometres, 100 nanometres and 200 nanometres. The focusing of the particle beams 3 for shaping the beam spots 5 is carried out by the objective lens system 100.

The primary particles incident on the object generate interaction products, e.g. secondary electrons, backscattered electrons or primary particles which have experienced a reversal of movement for other reasons and which emanate from the surface of the object 7 or from the first plane 101. The interaction products emanating from the surface of the object 7 are shaped by the objective lens 102 to form secondary particle beams 9. The particle beam system 1 provides a particle beam path 11 for guiding the plurality of secondary particle beams 9 to a detector system 200. The detector system 200 comprises a particle optical unit with a projection lens 205 for directing the secondary particle beams 9 at a particle multi-detector 209.

The detail I2 in FIG. 1 shows a plan view of the plane 211, in which individual detection regions of the particle multi-detector 209 on which the secondary particle beams 9 are incident at locations 213 are located. The incidence locations 213 lie in a field 217 with a regular pitch P2 with respect to one another. Exemplary values of the pitch P2 are 10 micrometres, 100 micrometres and 200 micrometres.

The primary particle beams 3 are generated in a beam generating apparatus 300 comprising at least one particle source 301 (e.g. an electron source), at least one collimation lens 303, a multi-aperture arrangement 305 and a field lens 307. The particle source 301 generates a diverging particle beam 309, which is collimated or at least substantially collimated by the collimation lens 303 in order to shape a beam 311 which illuminates the multi-aperture arrangement 305.

The detail I3 in FIG. 1 shows a plan view of the multi-aperture arrangement 305. The multi-aperture arrangement 305 comprises a multi-aperture plate 313, which has a plurality of openings or apertures 315 formed therein. Midpoints 317 of the openings 315 are arranged in a field 319 that is imaged onto the field 103 formed by the beam spots 5 in the object plane 101. A pitch P3 between the midpoints 317 of the apertures 315 can have exemplary values of 5 micrometres, 100 micrometres and 200 micrometres. The diameters D of the apertures 315 are smaller than the pitch P3 between the midpoints of the apertures. Exemplary values of the diameters D are 0.2×P3, 0.4×P3 and 0.8×P3.

Particles of the illuminating particle beam 311 pass through the apertures 315 and form particle beams 3. Particles of the illuminating beam 311 which are incident on the plate 313 are absorbed by the latter and do not contribute to the formation of the particle beams 3.

On account of an applied electrostatic field, the multi-aperture arrangement 305 focuses each of the particle beams 3 in such a way that beam foci 323 are formed in a plane 325. Alternatively, the beam foci 323 can be virtual. A diameter of the beam foci 323 can be, for example, 10 nanometres, 100 nanometres and 1 micrometre.

The field lens 307 and the objective lens 102 provide a first imaging particle optical unit for imaging the plane 325, in which the beam foci 323 are formed, onto the first plane 101 such that a field 103 of incidence locations 5 or beam spots arises there. If a surface of the object 7 is arranged in the first plane, the beam spots are correspondingly formed on the object surface.

The objective lens 102 and the projection lens arrangement 205 provide a second imaging particle optical unit for imaging the first plane 101 onto the detection plane 211. The objective lens 102 is thus a lens that is part of both the first and the second particle optical unit, while the field lens 307 belongs only to the first particle optical unit and the projection lens 205 belongs only to the second particle optical unit.

A beam switch 400 is arranged in the beam path of the first particle optical unit between the multi-aperture arrangement 305 and the objective lens system 100. The beam switch 400 is also part of the second optical unit in the beam path between the objective lens system 100 and the detector system 200.

Further information relating to such multi-beam particle beam systems and components used therein, such as, for instance, particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which in the full scope thereof is incorporated by reference in the present application.

The multiple particle beam system 1 furthermore comprises a computer system 10 configured both for controlling the individual particle optical components of the multiple particle beam system and for evaluating and analysing the signals obtained by the multi-detector 209. The computer system 10 can be constructed from a plurality of individual computers or components.

The multi-beam particle microscope 1 in accordance with FIG. 1 can comprise the components according to the disclosure, i.e. in particular one or more alignable magnetic lenses and the electrically controllable mechanical alignment and fixing mechanism. The computer system 10 can include the controller according to the disclosure, but the controller can also be provided separately.

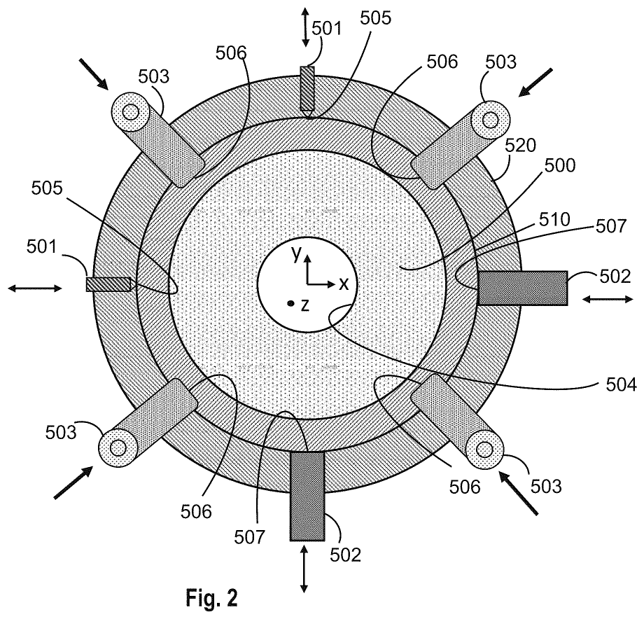

FIG. 2 schematically shows aspects of a Cartesian alignment of a magnetic lens 500. The illustration shows a section through the magnetic lens 500, the plane of the drawing corresponding to the alignment plane of the magnetic lens 500. The alignment plane is spanned by the vectors x and y. Oriented perpendicular thereto is the optical axis of the system or of the multi-beam particle microscope 1; the optical axis extends along the z-direction. The section illustrated schematically in FIG. 2 extends through the lens pot of the magnetic lens 500. The magnetic lens 500 is held by a mount 510, which is embodied in the form of a clamping ring 510 in the present example. The clamping ring holds the magnetic lens 500 in position by a clamping and thus via frictional force. The clamping ring also has an extent in the z-direction and in this way securely clamps the lens pot of the magnetic lens 500. The magnetic lens 500 together with its mount 510 is arranged in a housing 520. In the example shown, the housing 520 is a tubular portion that can form the outer housing of the multi-beam particle microscope. However, the housing can also be embodied differently or the concrete shape and design of a housing are greatly dependent on that location in the particle optical beam path at which the alignable magnetic lens 500 is actually arranged. In this respect, the illustration in FIG. 2 should be understood to be merely by way of example.

When the magnetic lens 500 is aligned correctly, a fanned-out particle beam or the multiplicity of individual particle beams 3 pass(es) through the opening 504 in the magnetic lens 500 centrally, wherein a centre ray or a beam arranged centrally within the field of the multi-beam particle beams is guided through the magnetic lens centre of the magnetic lens 500. In this case, the magnetic lens centre may deviate slightly from the geometric lens centre since it is not possible, on the basis of the geometric and mechanical characteristics of the magnetic lens 500, to predict exactly how the magnetic field generated by the magnetic lens 500 is actually shaped. A precise alignment is therefore used for precision applications with the multi-beam particle microscope 1.

In the example shown, alignment screws 501 are used for the alignment, the screws pressing onto the clamping ring 510 by way of an attachment point or attachment region 505 for the alignment in the x-direction or respectively y-direction and in this way displacing the magnetic lens 500 held in the clamping ring 510 in the x-direction or respectively y-direction. This displacement capability is indicated in each case by the double-headed arrows in FIG. 2. Displacements for the alignment are typically approximately 1 to 2 mm. Larger displacements are normally not required in practice. Arranged diametrically opposite each of the alignment screws 501 is a respective counterbearing 502, embodied in the form of a spring assembly in the example shown. In this way, the entire magnetic lens 500 can follow the movement of the alignment screws 501 within the alignment plane x, y.

In addition to the alignment mechanism 501 illustrated, FIG. 2 shows a fixing mechanism in the form of fixing screws 503, which each act on the clamping ring 510 and can thereby fix the position of the magnetic lens 500. In the example shown, the fixing direction of the fixing screws 503 is indicated by the single-headed arrows; in this case, the fixing direction is oriented obliquely with respect to the optical axis z and obliquely with respect to the alignment plane (x,y-plane). A corresponding fixing in this oblique direction makes it possible to fix the magnetic lens 500 both in the radial direction and in the axial direction (z-direction).

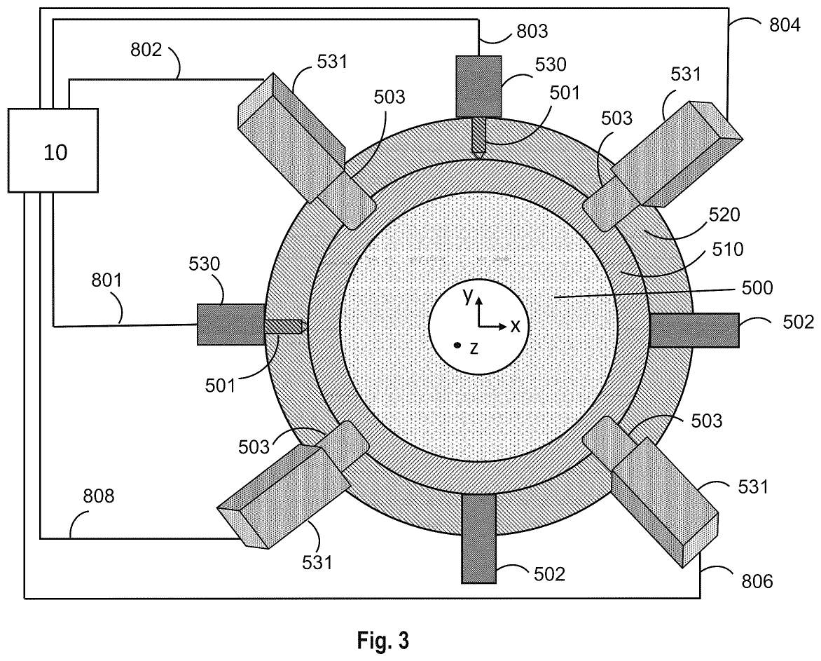

FIG. 3 then schematically shows an electrically controllable mechanical alignment and fixing of a global magnetic lens 500 in accordance with a first embodiment. Whereas a mechanical alignment is effected purely manually in FIG. 2, FIG. 3 shows the electrically controllable mechanical alignment and fixing according to the disclosure via an actuator system. The alignment screws 501 are now no longer operated manually; instead, actuators 530 are provided for the alignment. The controller 10 electrically controls the actuators 530. This allows a very precise and also documentable fine alignment of the alignment screws 501. In a similar manner, the fixing screws 503 are connected or coupled to an actuator 531 for the fixing. These actuators 531, too, are electrically controlled via the controller 10. The embodiment variant illustrated in FIG. 3 shows a retrofittable embodiment variant, in general. It is nevertheless pointed out that the embodiment variant illustrated in FIG. 3 should be understood to be merely by way of example and in no way restrictive for the disclosure.

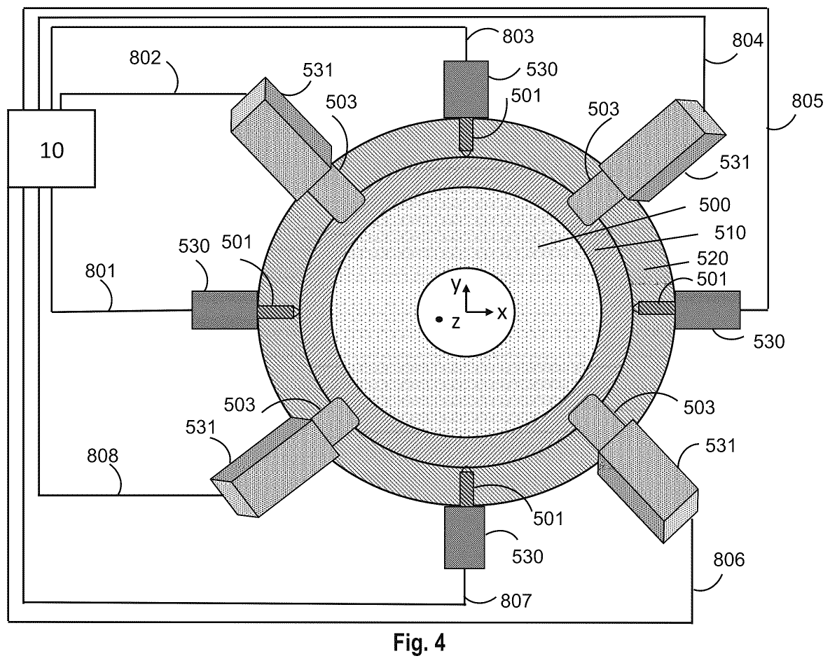

FIG. 4 schematically shows an electrically controllable mechanical alignment and fixing of a global magnetic lens 500 in accordance with a second embodiment. Compared with the embodiment variant illustrated in FIG. 3, in FIG. 4 the counterbearings or spring assemblies 502 are replaced by alignment screws 501 and an actuator system 530 coupled thereto. This has the effect that more signal lines 801 to 808 are admittedly provided. However, the situation now is that the signals from an alignment mechanism associated with a specific alignment direction are coupled to one another: The signals of the lines 801 and 805 control, oppositely and in coordination with one another in each case, the mutually associated first and second alignment units 530, 501 which position the magnetic lens 500 in the x-direction. The first and second alignment units 530, 501 assigned to one another can be structurally identical here, but they need not be structurally identical. In an analogous form, the signals of the lines 803 and 807 of the first and second alignment units 530, 501 which align the magnetic lens 500 in the y-direction are coordinated with one another and the control is effected oppositely. After alignment has been carried out, the four fixing units 531, 503 are then controlled via the signal lines 802, 804, 806 and 808.

In the embodiment variants illustrated in FIG. 3 and FIG. 4, the electrically controllable mechanical alignment and fixing mechanism is designed in multipartite fashion and in the form of two separate structural units (one structural unit-which is in turn multipartite-for the alignment and a further structural unit-which is in turn multipartite-for the fixing). However, it is also possible, of course, for the electrically controllable mechanical alignment and fixing mechanism to be embodied as one structural unit. This involves equipping the electrically controllable mechanical alignment and fixing mechanism with an actuator system combined in one component, and a restraint, on the other hand. It is then possible to dispense with separate fixing mechanisms.

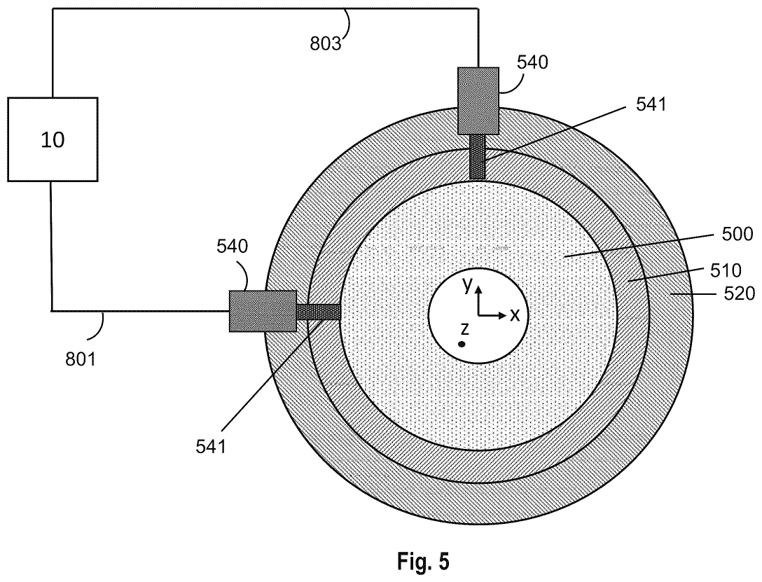

FIG. 5 schematically shows an electrically controllable mechanical alignment and fixing of a global magnetic lens 500 in accordance with a third embodiment. In this embodiment, the electrically controllable mechanical alignment and fixing mechanism is provided in a combined structural unit used both for alignment and for fixing. In accordance with the variant shown in FIG. 5, this combined alignment and fixing mechanism provides respectively an alignment and fixing mechanism for each alignment direction, that is to say that the combined alignment and fixing mechanism is in turn embodied in multipartite fashion. In the example shown, the magnetic lens 500 is coupled to an actuator 540 via a fixed connection such as a flexure 541, for example, such that the actuator 540 can displace the magnetic lens 500 in each case in the positive and negative x-direction or respectively y-direction. As a result, only one actuator 540 in each case is used for an alignment in the x-direction or respectively in the y-direction.

Moreover, it is also possible for the lens pot and lens cover of the magnetic lens 500 to be made alignable separately from one another. If the lens pot and lens cover are not arranged exactly centrally with respect to one another, it is thereby possible to simulate tiltings of the magnetic lens 500 and it is also possible to carry out a correction of a tilt in the particle beam system 1.

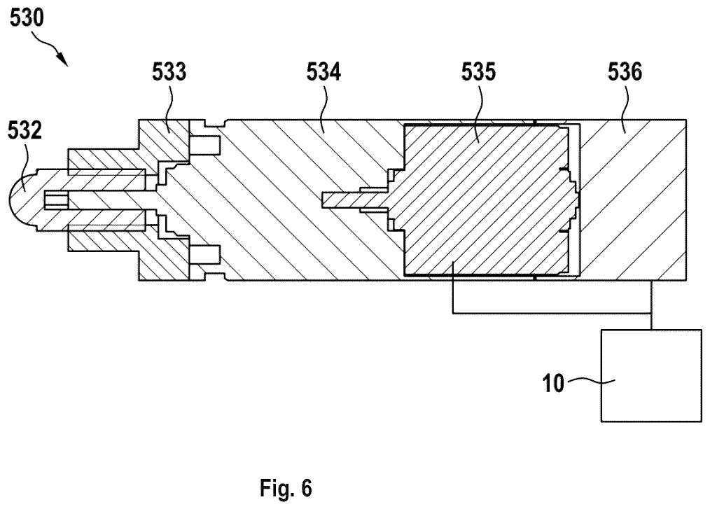

Additionally or alternatively, it is also possible to provide further actuating elements in the direction of the optical axis (z-direction), which can compensate for thermal effects, for example. In accordance with a further embodiment of the disclosure, the at least one alignable magnetic lens 500 is furthermore alignable and fixable in the direction of the optical axis (z-direction) of the system via a further electrically controllable mechanical alignment and fixing mechanism. In other words, an alignment in the z-direction can also be performed with a corresponding actuator system.

Whereas the actuators 530, 531 and 540 are merely illustrated conceptionally in FIGS. 3 to 5, FIGS. 6 and 7 schematically show concrete embodiments for an actuator system for alignment and fixing, respectively. FIG. 6 schematically shows an electrically controllable mechanical alignment mechanism 530 comprising a stepper motor 534 with gear mechanism. The motor 535 causes the gear mechanism 534 to effect a rotational movement, and a translational movement of the pressure pin 532 arises in interplay with the pin. A step counter 536 makes the position of the pressure pin 532 determinable and thus allows the alignment to be documented. For this purpose, the motor 535 and the step counter 536 are connected to the controller 10. The actuator 530 for the alignment is directly or indirectly connectable via a flange 533 to the magnetic lens 500 (not illustrated) to be aligned; by way of example, the flange 533 can be secured or screwed in at the housing 520 of a multi-beam particle microscope 1. Typical dimensions of the exemplary embodiment illustrated in FIG. 6 are a few centimetres in length and less than 2 cm in diameter. The achievable thrust forces are more than 150 N, for example more than 180 N, and an alignment accuracy is 0.01 μm or better.

FIG. 6 shows by way of example an embodiment of an actuator system with a linear gear mechanism. However, it is also possible, of course, to use a bevel gear mechanism instead of a linear gear mechanism or in addition to a linear gear mechanism. In this case, the choice of gear mechanism can be adapted to the available structural space/the geometric conditions.

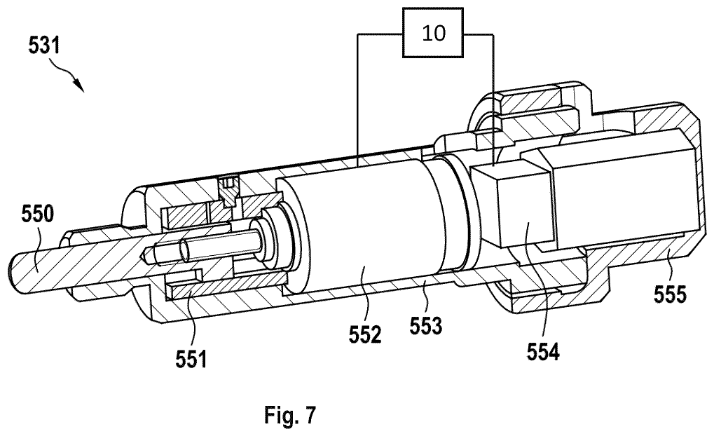

FIG. 7 schematically shows an electrically controllable mechanical fixing mechanism 531 comprising a two-stage actuator system with a stepper motor 552 and a piezoelement 554. The two-stage actuator system is arranged in a housing 553, which has a cover 555 in the example shown. A plunger 550 is arranged movably within a bush 551, and can be moved translationally via the motor 552. A comparatively large stroke can be realized by way of the motor 552. The piezoactuator 554 has a comparatively small stroke, but as the second stage supplies a further contact pressure by which the plunger 550 as the fixing element presses directly or indirectly on the magnetic lens 500 in order to fix the latter. This two-stage actuator system has proved to be desirable if the largest possible fixing force or holding force has to be applied to the magnetic lens 500 or an element of the mount 510 thereof. At least in the case of the second stage of the actuator system (piezoactuator 554), no rotations are used during application of the holding force, which enables a greater accuracy and a greater holding pressure/contact pressure.

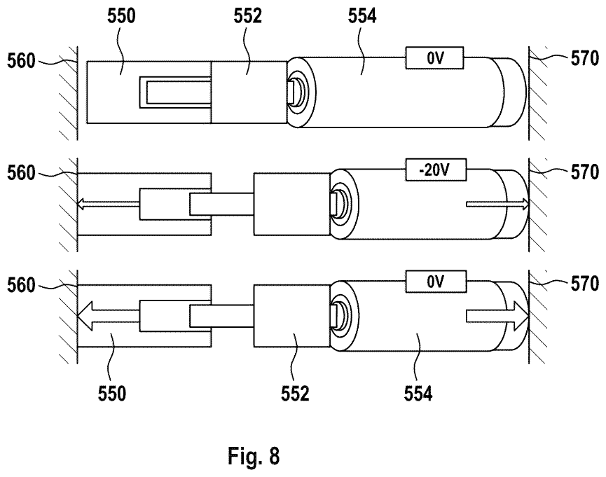

FIG. 8 illustrates a functional principle of the two-stage actuator system illustrated in FIG. 7: The situation without application of a contact pressure or holding force is illustrated at the top in FIG. 8.

A first stage of the actuator system is illustrated in the middle of FIG. 8: A negative voltage is applied to the piezoactuator 554 and the piezoactuator 554 therefore contracts or becomes shorter. A mechanical prestress is built up. In addition, the motor 552 with the spindle is controlled and the plunger 550 is driven and moved axially and the entire unit becomes braced between the mount of the magnetic lens 500 and the fixedly arranged piezoactuator 554. The bearing is illustrated merely schematically by the bearing regions 560 and 570 in FIG. 8.

In a second stage of the actuator system (cf. illustration at the bottom in FIG. 8), the electrical voltage is switched off again and the piezoactuator 554 attempts to become longer. Its mechanical prestress now presses on the motor 552 together with spindle and, mediated thereby, on the plunger 550. In this way, it is possible to build up a high fixing force on the mount 510 of the magnetic lens 500 or on the abovementioned clamping ring 510.

In the case of the embodiments of the actuator system described in greater detail by way of example, it can be desirable to operate them in an electrically load-free manner during operation of the multi-beam particle microscope 1. That means that during normal operation of the multi-beam particle microscope 1, no voltage need be present at the actuator, that is to say that no electromagnetic fields that could contribute to parasitic effects are present owing to the actuator system. Moreover, this fact should be assessed positively in the sense of the sustainability of the multi-beam particle microscope 1.

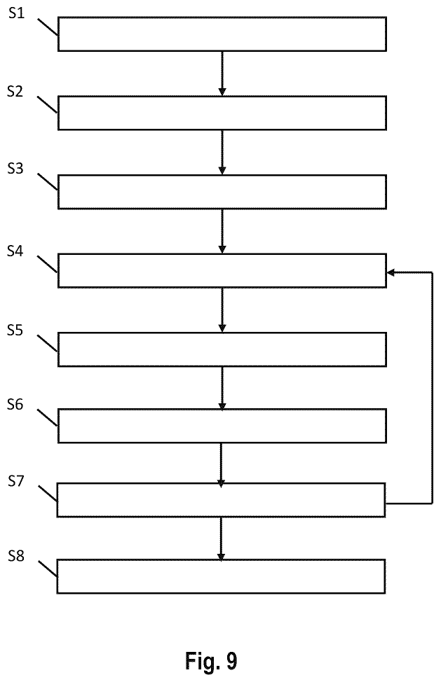

FIG. 9 schematically illustrates a method according to the disclosure for aligning a multi-beam particle microscope 1. The method for aligning the multi-beam particle microscope can be realized by an application of linear systems theory. It is an at least regionally valid statement that individual elements of a system behave linearly and that the behaviour of the overall system is constituted linearly from the individual elements. Against this background, a method for aligning the multi-beam particle microscope 1 can be designed as follows, for example:

A first method step S1 involves operating the multi-beam particle microscope 1 with a multiplicity of N actuated magnetic lenses 500, each comprising an electrically controllable mechanical alignment and fixing mechanism with an actuator system, wherein each actuator system allows the movement of one of the N magnetic lenses 500 with one or a plurality of degrees of freedom f.

A second method step S2 involves ascertaining a sensitivity of a change in position for each actuated magnetic lens 500 and per degree of freedom f of the actuated magnetic lens 500 and ascertaining associated influence vectors on the basis of the ascertained sensitivities.

A further method step S3 involves generating a particle optical image via the multi-beam particle microscope 1 and ascertaining an image aberration.

A fourth method step S4 involves determining a sum aberration vector for the ascertained image aberration.

A further method step S5 involves carrying out a singular value decomposition of the sum aberration vector with respect to the ascertained influence vectors and, on the basis thereof, ascertaining manipulated variables for each actuated magnetic lens 500 and for each degree of freedom f of the respectively actuated magnetic lens 500.

A further method step S6 involves electrically controlling the mechanical alignment and fixing mechanism of the actuated magnetic lenses 500 via the controller in accordance with the ascertained manipulated variables in order to reduce or eliminate the image aberration.

A further method step S7 involves generating a further particle optical image via the multi-beam particle microscope 1 and ascertaining a residual image aberration. If this residual image aberration is less than or equal to a predetermined upper limit, then the method ends with method step S8. Otherwise, method steps S4 to S7 are repeated.

It is possible to ascertain influence vectors for various operating points of the multi-beam particle microscope 1 and/or to store the influence vectors in a look-up table. In this way, an optimum alignment can be achieved for various operating points. It is even the case that this type of alignment of magnetic lenses is actually carried out for the first time for various operating points.

The supervised alignment and its reproducibility and also its electrical control additionally make it possible to carry out the above-described method for aligning the multi-beam particle microscope 1 in the form of remote maintenance. It is therefore not necessary for a technician on site to carry out the aligning. It is additionally possible, without relatively major disturbances even in the case of a multi-beam particle microscope installed in a production installation, to carry out an alignment or, if appropriate, realignment without appreciable disturbance of the overall operation.

The disclosure enables an automated alignment of a multi-beam particle microscope with high beam energies. In the case of high beam energies of, for example, more than 10 keV, in particular more than 20 keV, and in particular in the case of multi-beam systems, beam deflection by way of electrostatic deflectors, for example, is made more difficult. According to the disclosure, the alignment is instead carried out by way of a mechanical position alteration of in particular magnetic lenses. In this case, a lateral position alteration is described in the exemplary embodiments. An equivalent position alteration comprises a tilt in at least one direction of a magnetic lens. Generally, a mechanical position alteration also comprises an offset of magnetic lenses in the axial or z-direction.

Besides magnetic lenses, the mechanical position of electrostatic elements, too, can be altered.

### LIST OF REFERENCE SIGNS

1 Multi-beam particle microscope
3 Primary particle beams (individual particle beams)
5 Beam spots, incidence locations
7 Object
9 Secondary particle beams (individual particle beams)
10 Computer system, controller
11 Secondary particle beam path
13 Primary particle beam path
25 Sample surface, wafer surface
100 Objective lens system
101 Object plane
102 Objective lens
103 Field
200 Detector system
205 Projection lens
209 Particle multi-detector
211 Detection plane
213 Incidence locations
215 Detection region
217 Field
300 Beam generating apparatus
301 Particle source
303 Collimation lens system; condenser lens system
305 Multi-aperture arrangement, multi-beam generator
307 Field lens
309 Diverging particle beam
311 Illuminating particle beam
313 Multi-aperture plate
315 Openings in the multi-aperture plate
317 Midpoints of the openings
319 Field
323 Beam foci
325 Intermediate image plane
327 Field
400 Beam switch
500 Magnetic lens
501 Alignment screw with fine thread
502 Counterbearing, spring assembly
503 Fixing screw
504 Opening
505 Attachment point or attachment region for alignment
506 Attachment point or attachment region for fixing
507 Attachment point or attachment region for counterbearing
510 Mount, clamping ring
520 Housing
530 Actuator for alignment
531 Actuator for fixing
532 Pressure pin
533 Flange
534 Gear mechanism
535 motor
536 Step counter
540 Actuator for alignment and fixing
541 Connection element, e.g. flexure
550 Pressure element, e.g. plunger
551 Bush
552 Motor with spindle
553 Housing
554 Piezoactuator
555 Housing cover
560 Bearing region
570 Bearing region
801 Signal line
802 Signal line
803 Signal line
804 Signal line
805 Signal line
806 Signal line
807 Signal line
808 Signal line

1. A multi-beam particle microscope, comprising:
a particle source configured to generate a divergent beam of charged particles;
a condenser lens system configured to have the beam of charged particles pass therethrough;
a multi-beam generator downstream of the condenser lens system in a direction of a beam path of the charged particles so that at least some charged particles pass through openings in the multi-beam generator to provide a plurality of individual charged particle beams, the multi-beam generator configured to generate a first field of a multiplicity of first individual charged particle beams;
a first particle optical unit with a first particle optical beam path, the first particle optical unit configured to image the first individual charged particle beams onto a sample surface in an object plane so that the first individual charged particle beams are incident on the sample surface at incidence locations defining a second field;
a detection system comprising a multiplicity of detection regions defining a third field;
a second particle optical unit with a second particle optical beam path, the second particle optical unit configured to image second individual charged particle beams, emanating from the incidence locations in the second field, onto the third field;
a magnetic and/or electrostatic objective lens configured so that both the first and second individual charged particle beams pass therethrough;
a beam switch in the first particle optical beam path between the multi-beam generator and the objective lens, the beam switch being in the second particle optical beam path between the objective lens and the detection system, wherein at least one member selected from the group consisting of the condenser lens, the first particle optical unit and the second particle optical unit comprises an alignable magnetic lens disposed in a housing via a mount so that charged particles pass through the alignable magnetic lens;
an electrically controllable mechanical alignment and fixing mechanism comprising an actuator system, the electrically control the electrically controllable mechanical alignment and fixing mechanism being configured to mechanically align and mechanically fix a position of the alignable magnetic lens in a particle optical beam path in a plane orthogonal to an optical axis of the multi-beam particle microscope; and
a controller configured to electrically control the electrically controllable mechanical alignment and fixing mechanism.

2. The multi-beam particle microscope of claim 1, wherein:
the electrically controllable mechanical alignment and fixing mechanism is multipartite;
the electrically controllable mechanical alignment and fixing mechanism comprises an electrically controllable mechanical alignment mechanism; and
the electrically controllable mechanical alignment and fixing mechanism comprises an electrically controllable mechanical fixing mechanism; and
the electrically controllable mechanical fixing mechanism is a separate structural unit from the electrically controllable mechanical alignment mechanism.

3. The multi-beam particle microscope of claim 2, wherein:
the electrically controllable mechanical alignment mechanism comprises as actuator a stepper motor with gear mechanism; and/or
the electrically controllable mechanical fixing mechanism comprises as actuator a combination comprising a stepper motor and a piezoelement.

4. The multi-beam particle microscope of claim 2, wherein the electrically controllable mechanical fixing mechanism comprises an at least two-stage actuator system configured to generate a contact pressure for the fixing mechanism.

5. The multi-beam particle microscope of claim 2, wherein:
the electrically controllable mechanical alignment mechanism is configured for a Cartesian alignment; and
the electrically controllable mechanical alignment mechanism comprises two first alignment units arranged orthogonally to one another to align the position of the at least one magnetic lens within the plane orthogonal to the optical axis of the multi-beam particle beam system.

6. The multi-beam particle microscope of claim 5, wherein:
each of the two first alignment units is on the housing; and
for each of the two first alignment units, the first alignment unit comprises a pressure screw which is movable within the plane orthogonal to the optical axis via an actuator assigned to the alignment unit; and
for each of the two first alignment units, the first alignment unit is coupled to the magnetic lens via the mount of the magnetic lens to alter the position of the magnetic lens.

7. The multi-beam particle microscope of claim 6, further comprising, for each of the two first alignment units, a counterbearing on the housing at a position diametrically opposite the first alignment unit relative to the optical axis.

8. The multi-beam particle microscope of claim 6, further comprising, for each of the two first alignment units, an associated second alignment unit on the housing at a position diametrically opposite the first alignment unit relative to the optical axis, wherein the controller is configured to control the associated first and second alignment units oppositely in coordination with one another.

9. The multi-beam particle microscope of claim 2, wherein the electrically controllable mechanical fixing mechanism comprises a plurality of separate fixing units, and each separate fixing unit is configured to on an element of the mount of the magnetic lens to fix the position of the magnetic lens.

10. The multi-beam particle microscope of claim 9, wherein the separate fixing units are configured to fix the position of the magnetic lens via a frictional force or geometric blocking.

11. The multi-beam particle microscope of claim 10, wherein each of the plurality of fixing units is between alignment units adjacent to one another or between an alignment unit and a counterbearing adjacent to the alignment unit.

12. The multi-beam particle microscope of claim 1, wherein the electrically controllable mechanical alignment and fixing mechanism comprises a combined electrically controllable mechanical alignment and fixing mechanism.

13. The multi-beam particle microscope of claim 12, wherein the electrically controllable mechanical alignment and fixing mechanism does not comprise two functionally different separate structural units.

14. The multi-beam particle microscope of claim 12, wherein the combined electrically controllable mechanical alignment and fixing mechanism comprises a plurality of combined electrically controllable mechanical alignment and fixing mechanism.

15. The multi-beam particle microscope of claim 1, wherein the magnetic lens comprises a lens pot and a lens cover, and wherein the lens pot and the lens cover are alignable and fixable independently of one another via the electrically controllable mechanical alignment and fixing mechanism.

16. The multi-beam particle microscope of claim 1, further comprising a further electrically controllable mechanical alignment and fixing mechanism configured to align and fix the magnetic lens.

17. The multi-beam particle microscope of claim 1, wherein the magnetic lens comprises a member selected from the group consisting of a condenser lens, a field lens, and a projection lens.

18. The multi-beam particle microscope of claim 1, wherein the actuator system comprises electrically load-free actuators.

19.-20. (canceled)

21. A method, comprising:
a) operating a multi-beam particle microscope using a multiplicity of N actuated magnetic lenses, each actuated magnetic lens comprising an electrically controllable mechanical alignment and fixing mechanism comprising an actuator system, each actuator system allowing movement of one of the N actuated magnetic lenses with at least one degree of freedom;
b) ascertaining a sensitivity of a change in position for each actuated magnetic lens and per degree of freedom of each actuated magnetic lens and ascertaining associated influence vectors based on the ascertained sensitivities;
c) generating a particle optical image via the multi-beam particle microscope and ascertaining an image aberration;
d) determining a sum aberration vector for the ascertained image aberration;
e) singular value decomposing the sum aberration vector with respect to the ascertained influence vectors and, on the basis thereof, ascertaining manipulated variables for each actuated magnetic lens and for each degree of freedom of the actuated magnetic lens; and
f) electrically controlling the mechanical alignment and fixing mechanism of the actuated magnetic lenses via the controller in accordance with the ascertained manipulated variables in order to reduce or eliminate the image aberration.

22.-26. (canceled)
